(19) United States
(12) Patent Application Publication
(10) Pub. No.: US 2026/0297341 A1
(43) Pub. Date: Oct. 1, 2026

(54) PROTECTIVE FILM AGENT, PROTECTIVE FILM FORMING METHOD, AND CHIP MANUFACTURING METHOD

(71) Applicant: DISCO CORPORATION, Tokyo (JP)

(72) Inventor: Senichi Ryo, Tokyo (JP)

(21) Appl. No.: 19/544,143

(22) Filed: Feb. 19, 2026

(30) Foreign Application Priority Data
Mar. 31, 2025 (JP) 2025-058824

(51) Int. Cl. C09D 5/32; C09D 7/48; C09D 7/63; C09D 101/28; C09D 129/04; C09D 139/06; H10F 71/00; H10P 58/00

(52) U.S. Cl. CPC C09D 5/32; C09D 7/48; C09D 7/63; C09D 101/284; C09D 129/04; C09D 139/06; H10F 71/136; H10P 58/00

(57) ABSTRACT

Provided is a protective film agent for forming a protective film on one surface of a workpiece before processing the workpiece, in which the protective film agent is a solution including water-soluble resin, water, and a light absorbent, the light absorbent has a flavone structure, a flavonol structure, or an isoflavone structure, and the protective film agent contains 52.00 parts by mass or more of the light absorbent relative to 100 parts by mass of the water-soluble resin. Incidentally, the water-soluble resin is polyvinyl alcohol, polyvinylpyrrolidone, hydroxypropyl cellulose, or polyoxazoline, for example. In addition, the light absorbent is αGR, for example.

### BACKGROUND OF THE INVENTION

### Field of the Invention

The present invention relates to a protective film agent for forming a protective film on one surface of a workpiece before processing the workpiece, a protective film forming method for forming the protective film on the one surface of the workpiece, and a chip manufacturing method for manufacturing chips by dividing the workpiece having a plurality of devices formed therein along boundaries between the plurality of devices after forming the protective film on the one surface of the workpiece.

### Description of the Related Art

Chips of devices such as integrated circuits (ICs) are indispensable constituent elements in various kinds of electronic apparatuses such as mobile telephones and personal computers. Such chips are manufactured by, for example, dividing a workpiece such as a wafer having a plurality of devices formed therein along boundaries between the plurality of devices.

Apparatuses used to divide the workpiece include a laser processing apparatus, for example. This laser processing apparatus, for example, effects laser ablation by irradiating the workpiece with a laser beam having a wavelength that is absorbed by the workpiece. The laser processing apparatus can thereby partially remove the workpiece.

However, when the laser ablation occurs in the workpiece, debris may be scattered and adhere to the workpiece. In this case, the quality of chips obtained by dividing the workpiece may be decreased. In consideration of this, forming a protective film on one surface of the workpiece before the irradiation of the workpiece with the laser beam has been proposed (see Japanese Patent Laid-Open No. 2024-119588, for example).

This protective film is formed by coating the one surface of the workpiece with a protective film agent as a solution including α-glucosyl rutin (αGR) capable of absorbing ultraviolet (UV) rays as a light absorbent, and then drying the protective film agent applied to the one surface. It is thereby possible to prevent the debris from adhering to the one surface of the workpiece at a time of irradiating the workpiece with the laser beam from the one surface side.

### SUMMARY OF THE INVENTION

The protective film agent is a solution obtained by dissolving, in water, not only the light absorbent but also various kinds of materials such as water-soluble resin, and may become turbid during storage thereof. Further, when a protective film is formed from the turbid protective film agent, the quality of the protective film can change. In this case, accuracy at a time of processing the workpiece via the protective film by applying the laser beam may vary, and thus the reliability of the processing may be impaired.

In view of this, it is an object of one aspect of the present invention to provide a protective film agent that is less likely to become turbid during storage thereof.

The present inventors have completed the present invention by finding that a protective film agent prepared in such a manner as to contain 52.00 parts by mass or more of a light absorbent having a flavone structure, a flavonol structure, or an isoflavone structure relative to 100 parts by mass of water-soluble resin is less likely to become turbid during storage.

Specifically, in accordance with an aspect of the present invention, there is provided a protective film agent for forming a protective film on one surface of a workpiece before processing the workpiece, in which the protective film agent is a solution including water-soluble resin, water, and a light absorbent, the light absorbent has a flavone structure, a flavonol structure, or an isoflavone structure, and the protective film agent contains 52.00 parts by mass or more of the light absorbent relative to 100 parts by mass of the water-soluble resin.

Incidentally, the water-soluble resin is preferably polyvinyl alcohol, polyvinylpyrrolidone, hydroxypropyl cellulose, or polyoxazoline. In addition, preferably, the light absorbent has the flavone structure, and the light absorbent is α-glucosyl rutin, for example.

Further, in the protective film agent according to one aspect of the present invention, content of metallic impurities is preferably equal to or less than 100 ppb.

In addition, the protective film agent according to one aspect of the present invention preferably further includes an antioxidant or/and a plasticizer. In this case, preferably, in the protective film agent, content of the antioxidant is 0.005 percent by mass or more, and content of the plasticizer is 2.5 percent by mass or more. Further, the antioxidant is preferably an L-ascorbic acid or an ascorbic acid derivative.

In accordance with another aspect of the present invention, there is provided a protective film forming method for forming a protective film on one surface of a workpiece before processing the workpiece, the protective film forming method including applying a protective film agent as a solution including water-soluble resin, water, and a light absorbent to the one surface, and forming the protective film by drying the protective film agent applied to the one surface, the light absorbent having a flavone structure, a flavonol structure, or an isoflavone structure, and the protective film agent containing 52.00 parts by mass or more of the light absorbent relative to 100 parts by mass of the water-soluble resin.

In accordance with a further aspect of the present invention, there is provided a chip manufacturing method for manufacturing chips by dividing a workpiece in which a plurality of devices are formed, along boundaries between the plurality of devices, the chip manufacturing method including applying a protective film agent as a solution including water-soluble resin, water, and a light absorbent to one surface of the workpiece, forming a protective film by drying the protective film agent applied to the one surface, partially removing the protective film and partially exposing the workpiece by irradiating the workpiece with a pulsed laser beam having a wavelength that is absorbed by the light absorbent along the boundaries from the one surface side on which the protective film is formed, and dividing the workpiece into a plurality of chips by subjecting the workpiece to plasma etching with the partially removed protective film used as a mask, the light absorbent having a flavone structure, a flavonol structure, or an isoflavone structure, and the protective film agent containing 52.00 parts by mass or more of the light absorbent relative to 100 parts by mass of the water-soluble resin.

In accordance with a still further aspect of the present invention, there is provided a chip manufacturing method for manufacturing chips by dividing a workpiece on which a plurality of devices are formed, along boundaries between the plurality of devices, the chip manufacturing method including applying a protective film agent as a solution including water-soluble resin, water, and a light absorbent to one surface of the workpiece, forming a protective film by drying the protective film agent applied to the one surface, and partially removing each of the protective film and the workpiece and dividing the workpiece into a plurality of chips by irradiating the workpiece with a pulsed laser beam having a wavelength that is absorbed by each of the light absorbent and the workpiece along the boundaries from the one surface side on which the protective film is formed, the light absorbent having a flavone structure, a flavonol structure, or an isoflavone structure, and the protective film agent containing 52.00 parts by mass or more of the light absorbent relative to 100 parts by mass of the water-soluble resin.

Incidentally, each of the plurality of devices is preferably an image sensor.

According to one aspect of the present invention, a protective film agent that is less likely to become turbid during storage thereof is provided.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a flowchart schematically illustrating an example of a protective film forming method for forming a protective film on one surface of a workpiece before processing the workpiece;

FIG. 2A is a perspective view schematically illustrating an example of the workpiece available before a protective film agent is applied to the one surface;

FIG. 2B is a partial enlarged sectional view schematically illustrating the workpiece illustrated in FIG. 2A;

FIG. 3A is a perspective view schematically illustrating a state in an applying step;

FIG. 3B is a partial enlarged sectional view schematically illustrating the workpiece obtained after a protective film forming step;

FIG. 4 is a flowchart schematically illustrating an example of a chip manufacturing method for manufacturing chips by dividing the workpiece;

FIG. 5A is a perspective view schematically illustrating a state in an exposing step;

FIG. 5B is a partial enlarged sectional view schematically illustrating the workpiece obtained after the exposing step;

FIG. 6A is a diagram schematically illustrating an example of a plasma etching apparatus that is used in a dividing step;

FIG. 6B is a partial enlarged sectional view schematically illustrating the chips manufactured in the dividing step;

FIG. 7 is a flowchart schematically illustrating another example of the chip manufacturing method for manufacturing the chips by dividing the workpiece;

FIG. 8A is an optical microscopic image illustrating a linear groove obtained after formation of the groove that penetrates a protective film formed from a protective film agent of an example and partially exposes the workpiece and cleaning of the workpiece with water to remove the protective film; and

FIG. 8B is an optical microscopic image illustrating a linear groove obtained after formation of the groove that penetrates a protective film formed from a protective film agent of a comparative example and partially exposes the workpiece and cleaning of the workpiece with water to remove the protective film.

### DETAILED DESCRIPTION OF THE PREFERRED EMBODIMENT

A protective film agent according to one aspect of the present invention is a solution including water-soluble resin, water, and a light absorbent. The water-soluble resin is a main component of a protective film to be formed by applying the protective film agent to one surface of a workpiece and then drying the protective film agent. The light absorbent absorbs a laser beam having a predetermined wavelength, and causes laser ablation in the protective film formed on the one surface of the workpiece.

The water-soluble resin included in the protective film agent is, for example, polyvinyl alcohol (PVA), polyvinylpyrrolidone (PVP), or polyvinyl alcohol into which a modified group is introduced (for example, GOHSENX manufactured by Mitsubishi Chemical Corporation), hydroxypropyl cellulose (HPC), polyoxazoline, polyethylene glycol, polyethylene oxide, methyl cellulose, ethyl cellulose, polyacrylic acid, poly-N-vinylacetamide, polystyrene sulfonate, polyester, special nylon, phenolic resin, methylolmelamine resin, polyglycerin, or a graft polymer of these (for example, one in which polyvinylpyrrolidone is grafted to polyvinyl alcohol or the like). In addition, the protective film agent may include two or more kinds of the water-soluble resin described above.

There are a plurality of kinds of products as commercially available PVA. These products are classified according to a degree of polymerization and a degree of saponification. Incidentally, PVA having a saponification degree of 98.0 mol % or more is expressed also as a completely saponified product. In addition, PVA having a saponification degree equal to or less than 98.0 mol % but equal to or more than 90.0 mol % is expressed also as an intermediate saponified product. In addition, PVA having a saponification degree equal to or less than 90.0 mol % but equal to or more than 78.5 mol % is expressed also as a partially saponified product. A product having a polymerization degree of approximately 500 and a saponification degree of approximately 88, for example, is given a product name “PVA 5-88.” A product having a polymerization degree equal to or more than 300 but equal to or less than 3000 and a saponification degree equal to or less than 90.0 mol % is preferably applied as PVA to be included in the protective film agent. This is because, in a case where the polymerization degree of PVA having a saponification degree equal to or less than 90.0 mol % is less than 300, a large amount of PVA needs to be mixed into the protective film agent, making it difficult to manufacture the protective film agent, and in a case where the polymerization degree of the PVA exceeds 3000, the viscosity of the protective film agent is increased, making the liquid feeding of the protective film agent difficult.

In addition, there are also a plurality of kinds of products as commercially available PVP. These products are classified according to a K-value calculated by applying a relative viscosity value (25° C.) measured by a capillary viscometer to Fikentscher's viscosity equation. A product having a K-value of approximately 30, a product and having a K-value of approximately 60, and a product having a K-value of approximately 90, for example, are respectively given product names “PVP K-30,” “PVP K-60,” and “PVP K-90.” In addition, a product that has a K-value of approximately 85 and manufactured by NIPPON SHOKUBAI CO., LTD. is given a product name “PVP K-85N.” A product having a K-value of 50 or more is preferably applied as PVP to be included in the protective film agent. This is because, when the K-value of PVP is less than 50, a large amount of PVP needs to be mixed into the protective film agent, so that the manufacturing of the protective film agent becomes difficult and a change in quality such as a decrease in viscosity of the protective film agent and/or discoloration thereof tends to occur.

In addition, there are also a plurality of kinds of products as commercially available HPC. HPC is classified according to molecular weight. For example, as HPC manufactured by Nippon Soda Co., Ltd., there are a product having a molecular weight of approximately 40,000, a product having a molecular weight of approximately 100,000, and a product having a molecular weight of approximately 140,000, which are respectively given product names “HPC-SSL,” “HPC-SL,” and “HPC-L.” In addition, as HPC manufactured by Ashland Inc., there are a product having a molecular weight of approximately 80,000, a product having a molecular weight of approximately 95,000, and a product having a molecular weight of approximately 140,000, which are respectively given product names “Klucel-E,” “Klucel-L,” and “Klucel-J.” A product having a molecular weight of 80,000 or more is preferably applied as HPC to be included in the protective film agent. This is because, when the molecular weight of HPC is less than 80,000, a large amount of HPC needs to be mixed into the protective film, so that the manufacturing of the protective film becomes difficult and a change in quality such as a decrease in viscosity of the protective film agent and/or the occurrence of turbidity tends to occur.

The water included in the protective film agent may be tap water or the like, but is preferably pure water from a viewpoint of reducing the content of metallic impurities such as sodium (Na) in the protective film agent.

The light absorbent included in the protective film agent has a flavone structure, a flavonol structure, or an isoflavone structure. In particular, the light absorbent preferably has a flavone structure and further has a sugar chain. For example, this light absorbent is αGR. Incidentally, while the part of the flavone structure in αGR is hydrophobic, a remaining part therein is strongly hydrophilic.

Moreover, the protective film agent is prepared in such a manner as to contain 52.00 parts by mass or more of the light absorbent relative to 100 parts by mass of the water-soluble resin. This makes the protective film agent less likely to become turbid during storage. Reasons therefor will be described in the following.

When the amount of the water-soluble resin dissolved in the water is increased to such a degree that the light absorbent is less than 52.00 parts by mass relative to 100 parts by mass of the water-soluble resin, the light absorbent (for example, αGR) having strong hydrophilicity as a whole interacts with the water-soluble resin dissolved in the water, and the water-soluble resin tends to agglomerate. On the other hand, when the protective film agent is prepared in such a manner as to contain 52.00 parts by mass or more of the light absorbent relative to 100 parts by mass of the water-soluble resin, the agglomeration of such water-soluble resin is suppressed, and therefore turbidity of the protective film agent due to the agglomeration is also suppressed.

In addition, the protective film agent is preferably prepared in such a manner as to contain 300 parts by mass or less of the light absorbent relative to 100 parts by mass of the water-soluble resin. This is because, when the protective film agent is prepared in such a manner as to contain over 300 parts by mass of the light absorbent relative to 100 parts by mass of the water-soluble resin, there is a risk that the water-soluble resin and the light absorbent may separate from each other when the protective film is formed and consequently accuracy at a time of processing the workpiece via the protective film may be decreased.

Further, the protective film agent may include an organic solvent. For example, the protective film agent may be prepared such that the content of the organic solvent is 3 to 18 percent by mass. In this case, the agglomeration of the water-soluble resin or/and the light absorbent is suppressed to improve the stability of the protective film agent, and the surface tension of the protective film agent is decreased, so that the protective film agent is more easily applied to the one surface of the workpiece to make the surface thereof flat.

Cited as this organic solvent is, for example, methyl alcohol, ethyl alcohol, isopropyl alcohol, an ester, alkylene glycol monoalkyl ether, alkylene glycol, alkylene glycol monoalkyl ether acetate, or the like. Incidentally, propylene glycol monomethyl ether (PGME) is preferred as alkylene glycol monoalkyl ether. In addition, the protective film agent may include two or more kinds of organic solvents.

In addition, the protective film agent may include an antioxidant. For example, the protective film agent may be prepared such that the content of the antioxidant is 0.005 percent by mass or more. In this case, a structural change in the light absorbent is suppressed, so that stability thereof is improved. As a result, the discoloration of the protective film agent during storage can be suppressed. In addition, the protective film agent is preferably prepared such that the content of the antioxidant is 0.05 percent by mass or less, for example. This is because, when the protective film agent is prepared such that the content of the antioxidant in the protective film agent exceeds 0.05 percent by mass, it may be difficult to suppress the discoloration of the protective film agent during storage.

Cited as this antioxidant is, for example, an L-ascorbic acid (ASC) (what is generally called vitamin C), an ascorbic acid derivative, or the like. In addition, the protective film agent may include two or more kinds of antioxidants.

In addition, the protective film agent may include a plasticizer. For example, the protective film agent may be prepared such that the content of the plasticizer is 2.50 percent by mass or more. In this case, the film thickness of the protective film agent applied to the one surface of the workpiece is increased, and a structural change in the light absorbent is suppressed, so that stability thereof is improved. Further, in this case, accuracy at a time of processing the workpiece by performing plasma etching while using a protective film formed from the protective film agent as a mask is improved (see Japanese Patent Laid-Open No. 2024-119588 and the like). In addition, the protective film agent is preferably prepared such that the content of the plasticizer is 15 percent by mass or less, for example. This is because when the protective film agent is prepared such that the content of the plasticizer exceeds 15 percent by mass, the protective film formed from the protective film agent becomes too soft, and consequently accuracy may decrease when the workpiece is processed via the protective film.

Cited as this plasticizer is one described in Japanese Patent Laid-Open No. 2024-119588, for example. In addition, trimethylolpropane (TMP) is preferred as the plasticizer. In addition, the protective film agent may include two or more kinds of plasticizers.

In addition, another component may be included in addition to the antioxidant and the plasticizer. Cited as the other component is, for example, another water-soluble light absorbent (a cinnamic acid-based compound, a benzophenone-based compound, or an anthraquinone-based compound) other than αGR, a basic compound such as an ammonia-based compound or an amine-based compound, an acidic compound such as formic acid or acetic acid, a pH adjuster, a preservative, an antifoaming agent, a surfactant, a leveling agent, an ultraviolet curing agent (a reactive monomer and a photopolymerization initiator), or the like. In addition, the protective film agent may include two or more kinds of these components.

The protective film agent is, for example, prepared by filtering a solution obtained by dissolving the water-soluble resin in the water and then adding the light absorbent. Further, an antioxidant and/or a plasticizer may be further added to the solution obtained after the water-soluble resin is dissolved but before the light absorbent is dissolved. In addition, an organic solvent may be dissolved in the solution obtained after the water-soluble resin and the light absorbent are dissolved but before the filtering is performed.

In addition, an ion exchange may be performed in the solution obtained after the constituent elements added intentionally are all dissolved but before the filtering is performed. In this case, the content of metallic impurities in the protective film agent can be made equal to or less than 100 ppb, for example. As a result, the discoloration of the protective film agent during storage can be suppressed.

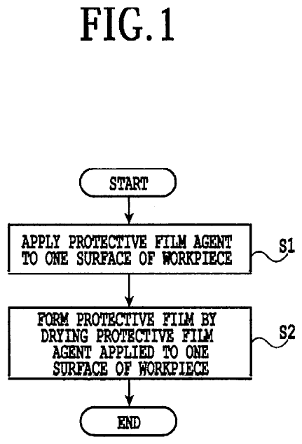

FIG. 1 is a flowchart schematically illustrating an example of a protective film forming method for forming the protective film on the one surface of the workpiece before processing the workpiece. This method first applies the protective film agent to the one surface of the workpiece (applying step S1).

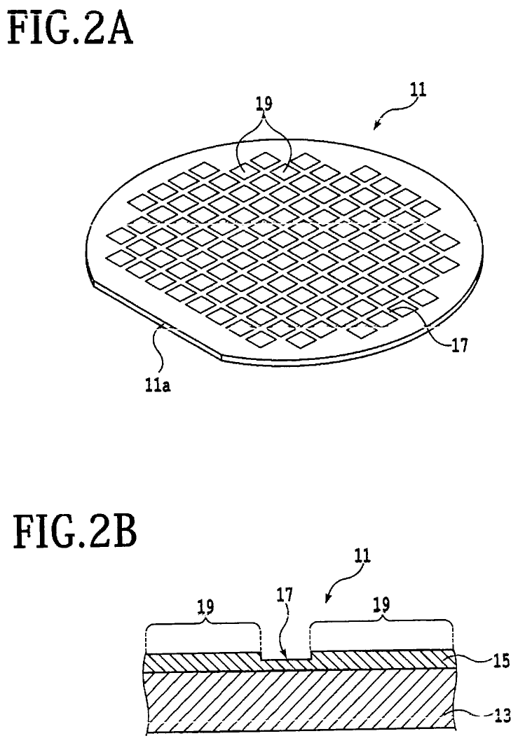

FIG. 2A is a perspective view schematically illustrating an example of the workpiece (workpiece 11) available before the protective film agent is applied to the one surface. FIG. 2B is a partial enlarged sectional view schematically illustrating the workpiece 11. The workpiece 11 is a disk-shaped wafer having an orientation flat 11a formed at an outer edge thereof for indicating a crystal orientation.

Specifically, the workpiece 11 has a substrate 13 in which silicon (Si), silicon carbide (SiC), or the like is used as a raw material. A part on a top surface (upper surface) side of the substrate 13 is provided with an impurity region doped with an impurity. In addition, the top surface of the substrate 13 is provided with a functional layer 15 including a plurality of insulating films and a plurality of conductive films.

In addition, the workpiece 11 is demarcated into a plurality of regions by streets 17 set in a lattice manner. Incidentally, linearly extending parts of the streets 17 are referred to also as planned dividing lines. Further, a device 19 is formed by a part (the impurity region and an intrinsic semiconductor region in which no impurities are present) of the substrate 13 included in each of the plurality of regions and a part (the insulating films and the conductive films) of the functional layer 15.

In other words, on one surface side of the workpiece 11, a plurality of devices 19 are provided in a matrix form, that is, such that boundaries thereof extend in a lattice manner. Incidentally, the functional layer 15 in the regions provided with the devices 19 is slightly thicker than the functional layer 15 of the streets 17. That is, the devices 19 form protruding portions slightly protruding upward from the streets 17.

Further, the workpiece 11 may be integrated with a ring frame via a supporting member that is fastened to another surface of the workpiece 11. This supporting member is, for example, a tape including an adhesive layer to be adhered to the other surface of the workpiece 11. Alternatively, the supporting member may be a sheet not including the adhesive layer. In this case, the workpiece 11 and the supporting member are fastened to each other by thermocompression bonding, for example.

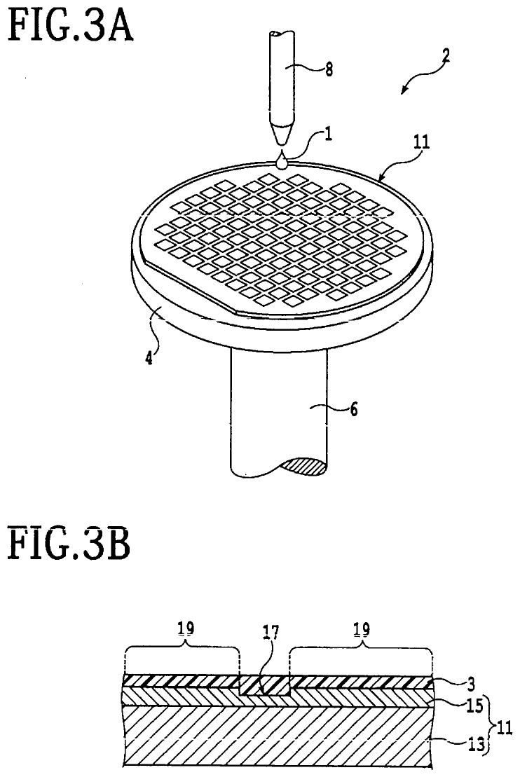

FIG. 3A is a perspective view schematically illustrating a state in the applying step S1. The applying step S1 is performed in a spin coater 2. This spin coater 2 includes a chuck table 4 having an upper surface in a circular shape.

A lower surface side of the chuck table 4 is coupled to a rotational driving source (not illustrated) including a motor or the like via a spindle 6. When the rotational driving source is operated, the chuck table 4 is rotated with a straight line along a vertical direction passing through the center of the upper surface as a rotational axis thereof.

The chuck table 4 includes a frame body, in which a recessed portion in a circular shape as viewed in plan is formed on the upper surface side of the chuck table 4, and a porous plate (not illustrated) in a disk shape, which is fixed to the recessed portion. The porous plate is formed by a porous member. The porous plate can selectively communicate with a suction source (not illustrated) including an ejector or the like or an air supply source including an air pump or the like, via a flow passage (not illustrated) formed in the frame body and the spindle 6.

When the suction source is operated in a state in which the flow passage is made to communicate with the suction source, the pressure of the flow passage becomes negative pressure, and a suction force acts on a space in the vicinity of an upper surface of the porous plate. When the air supply source is operated in a state in which the flow passage is made to communicate with the air supply source in place of the suction source, the pressure of the flow passage returns to atmospheric pressure, and the suction force acting on the space in the vicinity of the upper surface of the porous plate disappears.

A nozzle 8 for supplying a protective film agent 1 to the center of the upper surface of the porous plate and a vicinity thereof is provided above the chuck table 4. This nozzle 8 is coupled to a solution supply source (not illustrated) including a liquid feeding pump and a tank for storing the protective film agent 1 or the like via a pipe (not illustrated) or the like.

In the applying step S1, first, the workpiece 11 is placed on the chuck table 4 directly or via the supporting member such that the one surface of the workpiece 11 faces upward and the workpiece 11 covers the porous plate. Next, the suction source communicating with the porous plate is operated. A suction force thereby directly or indirectly acts on the workpiece 11 to hold the workpiece 11 on the upper surface of the chuck table 4.

Next, the solution supply source is operated in such a manner as to drop the protective film agent 1 onto the one surface side of the workpiece 11 from the nozzle 8. Next, the rotational driving source is operated in such a manner as to rotate the chuck table 4 via the spindle 6. What is generally called spin coating which applies the protective film agent 1 to the one surface of the workpiece 11 in such a manner as to cover the whole region of the workpiece 11 is thereby performed.

After the applying step S1 is performed, a protective film is formed by drying the protective film agent 1 applied to the one surface of the workpiece 11 (protective film forming step S2). FIG. 3B is a partial enlarged sectional view schematically illustrating the workpiece 11 obtained after the protective film forming step S2.

In the protective film forming step S2, the protective film agent 1 may be air-dried, or the protective film agent 1 may be dried while the atmosphere is heated and/or dehumidification is performed. A protective film 3 is thereby formed on the one surface of the workpiece 11.

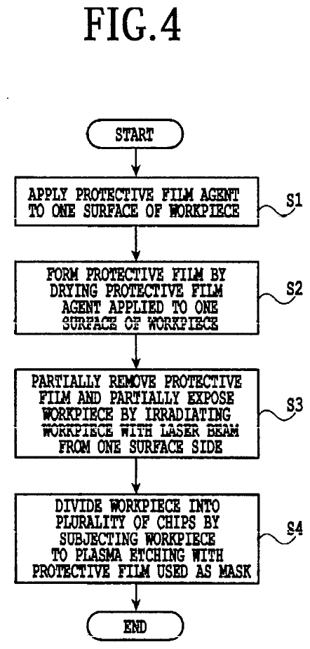

FIG. 4 is a flowchart schematically illustrating an example of a chip manufacturing method for manufacturing chips by dividing the workpiece 11 along the streets 17 (that is, boundaries between the plurality of devices 19) after forming the protective film 3 on the one surface of the workpiece 11.

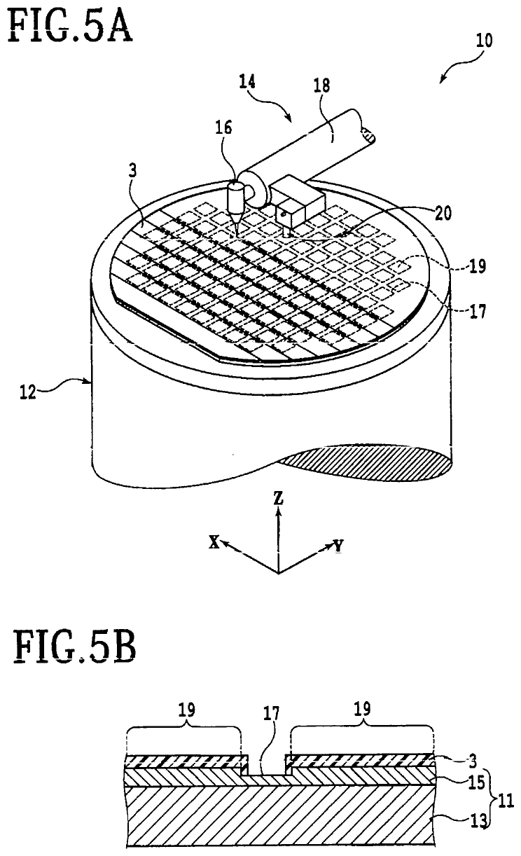

This method partially removes the protective film 3 and partially exposes the workpiece 11 by irradiating the workpiece 11 with a laser beam from the one surface side after performing the applying step S1 and the protective film forming step S2 (exposing step S3). FIG. 5A is a perspective view schematically illustrating a state in the exposing step S3. FIG. 5B is a partial enlarged sectional view schematically illustrating the workpiece 11 obtained after the exposing step S3.

Incidentally, a direction indicated by an arrow X illustrated in FIG. 5A (X-direction) and a direction indicated by an arrow Y (Y-direction) are directions orthogonal to each other in a horizontal plane, and a direction indicated by an arrow Z (Z-direction) is a direction (vertical direction) orthogonal to each of the X-direction and the Y-direction.

The exposing step S3 is performed in a laser processing apparatus 10. This laser processing apparatus 10 includes a chuck table 12 having an upper surface in a circular shape. The chuck table 12 is coupled to a rotational driving source (not illustrated) including a motor or the like via a spindle (not illustrated). When the rotational driving source is operated, the chuck table 12 is rotated with a straight line along the Z-direction passing through the center of the upper surface as a rotational axis thereof.

The chuck table 12 includes a frame body, in which a recessed portion in a circular shape as viewed in plan is formed on the upper surface side of the chuck table 12, and a porous plate (not illustrated) in a disk shape, which is fixed to the recessed portion. The porous plate is formed by a porous member. The porous plate can selectively communicate with a suction source (not illustrated) including an ejector or the like or an air supply source including an air pump or the like, via a flow passage (not illustrated) formed in the frame body and the spindle.

When the suction source is operated in a state in which the flow passage is made to communicate with the suction source, the pressure of the flow passage becomes negative pressure, and a suction force acts on a space in the vicinity of the upper surface of the porous plate. When the air supply source is operated in a state in which the flow passage is made to communicate with the air supply source in place of the suction source, the pressure of the flow passage returns to atmospheric pressure, and the suction force acting on the space in the vicinity of the upper surface of the porous plate disappears.

Further, an X-direction moving mechanism (not illustrated) and a Y-direction moving mechanism (not illustrated) each including a ball screw and the like, for example, are coupled to a lower surface side of the chuck table 12. When the X-direction moving mechanism is operated, the chuck table 12 is moved along the X-direction. When the Y-direction moving mechanism is operated, the chuck table 12 is moved along the Y-direction.

A head 16 of an irradiating unit 14 is provided above the chuck table 12. The irradiating unit 14 includes a laser oscillator (not illustrated). The laser oscillator has, for example, neodymium-yttrium-aluminum-garnet (Nd:YAG) or the like as a laser medium, and generates a pulsed laser beam having a wavelength (for example, 355 nm) that is absorbed by the light absorbent included in the protective film 3.

The laser beam is guided to the head 16 via an optical system including a lens and a mirror or the like housed in a housing 18, and is emitted directly downward from the head 16. Incidentally, in the irradiating unit 14, the laser beam is set to a repetition frequency of 5 to 50000 kHz, for example, is set to a pulse width equal to or more than 10 fs but equal to or less than 300 ns, for example, is set to a power equal to or higher than 0.01 W but equal to or lower than 100.0 W, for example, and is set to a beam width (spot diameter) equal to or more than 1 μm but equal to or less than 100 μm, for example, at a focused point of the laser beam.

In addition, a camera 20 is provided on a side of the head 16. The camera 20 includes, for example, a light source such as a light emitting diode (LED) for emitting light having a wavelength that passes through the protective film 3, an objective lens, and an imaging element such as a charge coupled device (CCD) image sensor or a complementary metal oxide semiconductor (CMOS) image sensor. The camera 20 can image a region directly below the camera 20.

Further, a Z-direction moving mechanism (not illustrated) including a ball screw and the like, for example, is coupled to the housing 18. When the Z-direction moving mechanism is operated, the head 16, the housing 18, and the camera 20 are moved along the Z-direction.

In the exposing step S3, first, the workpiece 11 is placed on the chuck table 12 directly or via the supporting member such that the protective film 3 faces upward and the workpiece 11 covers the porous plate. Next, the suction source communicating with the porous plate is operated. A suction force thereby directly or indirectly acts on the workpiece 11 to hold the workpiece 11 on the upper surface of the chuck table 12.

Next, the camera 20 images the one surface side of the workpiece 11. Subsequently, an image formed by this imaging is referred to, and the rotational driving source rotates the chuck table 12 via the spindle such that some of the plurality of planned dividing lines included in the streets 17 are parallel with the X-direction and remaining ones of the plurality of planned dividing lines are parallel with the Y-direction.

Thereafter, the Z-direction moving mechanism lifts or lowers the head 16 together with the housing 18 such that the focused point of the laser beam emitted from the head 16 is positioned at a height corresponding to the height of the protective film 3. Then, the X-direction moving mechanism and/or the Y-direction moving mechanism moves the chuck table 12 such that a specific planned dividing line included in the streets 17 is positioned in the X-direction or an opposite direction thereof as viewed in plan from the head 16.

Next, while the irradiating unit 14 is operated in such a manner as to emit the laser beam from the head 16, the X-direction moving mechanism moves the chuck table 12 along the X-direction such that the laser beam passes from one end to another end in the X-direction of the protective film 3. Laser ablation thereby occurs in a part of the protective film 3 irradiated with the laser beam, so that a part of the protective film 3 superposed on the planned dividing line is removed.

Then, the above-described operation is repeated until laser ablation is caused at all of the streets 17. As a result, parts of the protective film 3 superposed on the streets 17 are removed, so that the workpiece 11 is partially exposed.

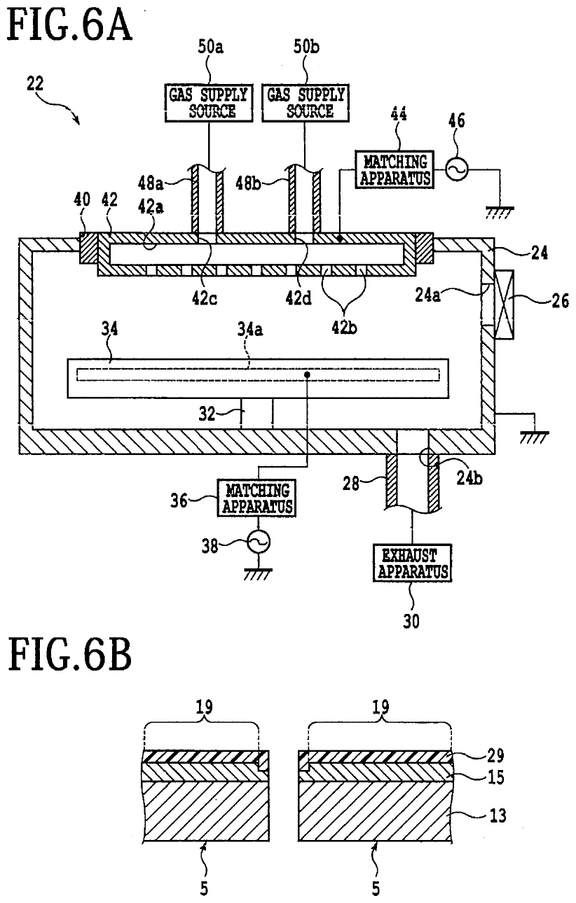

After the exposing step S3 is performed, the workpiece 11 is divided into a plurality of chips by being subjected to plasma etching with the protective film 3 used as a mask (dividing step S4). FIG. 6A is a diagram schematically illustrating an example of a plasma etching apparatus (plasma etching apparatus 22) that is used in the dividing step S4.

The plasma etching apparatus 22 has a chamber 24 that is formed of a conductive material and grounded. A loading and unloading port 24a for loading the workpiece 11 into the inside of the chamber 24 and unloading the workpiece 11 from the inside of the chamber 24 is formed in the chamber 24.

The loading and unloading port 24a is provided with a gate valve 26 that can shut off an internal space and an external space of the chamber 24 from each other or make the internal space and the external space communicate with each other. In addition, an exhaust port 24b for exhausting the internal space of the chamber 24 is formed in the chamber 24.

The exhaust port 24b communicates with an exhaust apparatus 30 such as a vacuum pump via a pipe 28 or the like. In addition, the inner surface of the chamber 24 is provided with a supporting member 32. This supporting member 32 supports a table 34.

Moreover, an upper portion of the table 34 is provided with an electrostatic chuck (not illustrated). In addition, an inner part of the table 34 is provided with a disk-shaped electrode 34a located below the electrostatic chuck. The electrode 34a is connected to a high-frequency power supply 38 via a matching apparatus 36.

In addition, an opening in a disk shape is formed in a position of the chamber 24 which faces an upper surface of the table 34. The opening is provided with a gas jetting head 42 that is supported by the chamber 24 via a bearing 40. The gas jetting head 42 is formed of a conductive material, and is connected to a high-frequency power supply 46 via a matching apparatus 44.

In addition, a cavity (gas diffusing space) 42a is formed within the gas jetting head 42. In addition, a plurality of gas discharge ports 42b for making the gas diffusing space 42a and the internal space of the chamber 24 communicate with each other are formed in a part on the inside (for example, a lower portion) of the gas jetting head 42. In addition, two gas supply ports 42c and 42d for supplying predetermined types of gas to the gas diffusing space 42a are formed in a part on the outside (for example, an upper portion) of the gas jetting head 42.

Further, the gas supply port 42c communicates via a pipe 48a or the like with a gas supply source 50a for supplying, for example, a fluorocarbon-based gas such as C₄F₈ and/or a sulfur fluoride-based gas such as SF₆ or the like. In addition, the gas supply port 42d communicates via a pipe 48b or the like with a gas supply source 50b for supplying, for example, an inert gas such as Ar and an O₂ gas or the like.

The dividing step S4 divides the workpiece 11 along boundaries between the plurality of devices 19 by, for example, what is generally called a Bosch process. Specifically, first, the workpiece 11 is loaded onto the table 34 such that the protective film 3 that is to serve as a mask faces upward in a state in which the gate valve 26 makes the internal space and the external space of the chamber 24 communicate with each other.

Next, the electrostatic chuck of the table 34 holds the workpiece 11. Subsequently, the exhaust apparatus 30 exhausts the internal space of the chamber 24, and sets the internal space of the chamber 24 in a vacuum state. Thereafter, isotropic plasma etching, formation of a side wall protective film, and anisotropic plasma etching are alternately repeated until the workpiece 11 is divided along the boundaries between the plurality of devices 19.

Specifically, the isotropic plasma etching is performed, for example, by providing high-frequency power from the high-frequency power supply 46 to the gas jetting head 42 in a state of supplying a gas including SF₆ from the gas supply source 50a to the internal space of the chamber 24 and supplying an Ar gas from the gas supply source 50b to the internal space of the chamber 24. Thus, the workpiece 11 exposed at the boundaries between the plurality of devices 19 is isotropically etched by F-based radicals or the like generated in the internal space of the chamber 24.

In addition, the formation of the side wall protective film is performed, for example, by providing high-frequency power from the high-frequency power supply 46 to the gas jetting head 42 in a state of supplying a gas including C₄F₈ from the gas supply source 50a to the internal space of the chamber 24 and supplying a gas including Ar from the gas supply source 50b to the internal space of the chamber 24. Thus, a film including fluorocarbon is formed with CF radicals deposited on the top surface of the workpiece 11 exposed at the boundaries between the plurality of devices 19 (specifically, a surface newly exposed by the isotropic plasma etching).

Alternatively, the formation of the side wall protective film may be performed by providing high-frequency power from the high-frequency power supply 46 to the gas jetting head 42 in a state of supplying a gas including O₂ and Ar from the gas supply source 50b to the internal space of the chamber 24. The material of the workpiece 11 (for example, the substrate 13) exposed at the boundaries between the plurality of devices 19 thereby reacts with oxygen ions, so that an oxide film is formed on the top surface of the workpiece 11.

In addition, the anisotropic plasma etching is performed, for example, by providing high-frequency power from the high-frequency power supply 38 to the electrode 34a provided within the table 34 and providing high-frequency power from the high-frequency power supply 46 to the gas jetting head 42 in a state of supplying a gas including SF₆ from the gas supply source 50a to the internal space of the chamber 24 and supplying an Ar gas from the gas supply source 50b to the internal space of the chamber 24. Thus, F-based ions or the like generated in the internal space of the chamber 24 are accelerated toward the table 34, and the workpiece 11 is thereby anisotropically etched.

FIG. 6B is a partial enlarged sectional view schematically illustrating chips manufactured in the dividing step S4. A plurality of chips 5 are manufactured when the workpiece 11 is divided along the boundaries between the plurality of devices 19.

Incidentally, in the dividing step S4, the workpiece 11 may be divided along the boundaries between the plurality of devices 19 by performing only the anisotropic plasma etching without performing the isotropic plasma etching and the formation of the side wall protective film.

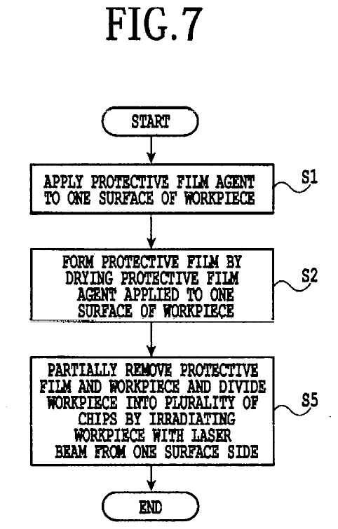

FIG. 7 is a flowchart schematically illustrating another example of the chip manufacturing method for manufacturing chips by dividing the workpiece 11 along the streets 17 (that is, the boundaries between the plurality of devices 19) after forming the protective film 3 on the one surface of the workpiece 11.

This method partially removes the protective film 3 and the workpiece 11 by irradiating the workpiece 11 with the laser beam from the one surface side after performing the applying step S1 and the protective film forming step S2. The method thereby divides the workpiece 11 into the plurality of chips 5 (dividing step S5).

This dividing step S5 is performed in a manner similar to that of the exposing step S3 except for, for example, the use of a laser beam having a wavelength that is absorbed by not only the light absorbent included in the protective film 3 but also the workpiece 11 (for example, silicon, silicon carbide, or the like as a raw material of the substrate 13) and except for the positioning of the focused point of the laser beam at a height corresponding to the height of the substrate 13. A detailed description of the dividing step S5 will therefore be omitted.

Besides, structures, methods, and the like according to the foregoing embodiment can be modified and implemented as appropriate without departing from the objective scope of the present invention.

### EXAMPLES

In the following, a description will be made of an experiment (Experiment 1) conducted to investigate tendencies to turbidity in the protective film agent as an example of the present invention. In Experiment 1, first, there were prepared protective film agents of Examples 1 through 16 which contain various kinds of materials at ratios (percent by mass) illustrated in Tables 1 through 5 below. Incidentally, a ratio of the light absorbent to the water-soluble resin in each of the protective film agents of Examples 1 through 16 is also illustrated in a section of “LIGHT ABSORBENT/WATER-SOLUBLE RESIN” in Tables 1 through 4. For example, the protective film agent of Example 1 contains 128.21 parts by mass of the light absorbent relative to 100 parts by mass of the water-soluble resin.

TABLE 1

| | EXAM- | EXAM- | EXAM- | EXAM- |
|---|---|---|---|---|
| | PLE 1 | PLE 2 | PLE 3 | PLE 4 |
| WATER-SOLUBLE | PVA 5- | PVA 5- | PVA 5- | PVA 5- |
| RESIN | 88: 7.80 | 88: 7.92 | 88: 8.10 | 88: 8.28 |
| WATER | 67.28 | 68.16 | 69.48 | 70.80 |
| LIGHT ABSORBENT | αGR: 10.00 | αGR: 9.00 | αGR: 7.50 | αGR: 6.00 |
| ORGANIC SOLVENT | PGME: 14.90 | PGME: 14.90 | PGME: 14.90 | PGME: 14.90 |
| ANTIOXIDANT | ASC: 0.015 | ASC: 0.015 | ASC: 0.015 | ASC: 0.015 |
| PLASTICIZER | — | — | — | — |
| LIGHT | 1.2821 | 1.1364 | 0.9259 | 0.7246 |
| ABSORBENT/WATER- | | | | |
| SOLUBLE RESIN | | | | |

TABLE 2

| | EXAM- | EXAM- | EXAM- | EXAM- |
|---|---|---|---|---|
| | PLE 5 | PLE 6 | PLE 7 | PLE 8 |
| WATER-SOLUBLE | PVA 5- | PVA 5- | PVA 5- | PVA 5- |
| RESIN | 88: 7.68 | 88: 8.04 | 88: 8.40 | 88: 9.61 |
| WATER | 61.91 | 69.54 | 71.68 | 70.47 |
| LIGHT ABSORBENT | αGR: 5.00 | αGR: 5.00 | αGR: 5.00 | αGR: 5.00 |
| ORGANIC SOLVENT | PGME: 14.90 | PGME: 14.90 | PGME: 14.90 | PGME: 14.90 |
| ANTIOXIDANT | ASC: 0.015 | ASC: 0.015 | ASC: 0.015 | ASC: 0.015 |
| PLASTICIZER | TMP: 10.50 | TMP: 2.50 | — | — |
| LIGHT | 0.6510 | 0.6219 | 0.5952 | 0.5203 |
| ABSORBENT/WATER- | | | | |
| SOLUBLE RESIN | | | | |

TABLE 3

| | EXAM- | EXAM- | EXAM- | EXAM- |
|---|---|---|---|---|
| | PLE 9 | PLE 10 | PLE 11 | PLE 12 |
| WATER-SOLUBLE | PVP K- | PVP K- | PVP K- | PVP K- |
| RESIN | 60: 11.90 | 90: 4.20 | 90: 4.35 | 90: 4.43 |
| WATER | 66.58 | 76.80 | 75.74 | 77.17 |
| LIGHT ABSORBENT | αGR: 7.50 | αGR: 5.00 | αGR: 5.00 | αGR: 3.50 |
| ORGANIC SOLVENT | PGME: 14.01 | PGME: 14.00 | PGME: 14.90 | PGME: 14.89 |
| ANTIOXIDANT | ASC: 0.010 | — | ASC: 0.010 | ASC: 0.010 |
| PLASTICIZER | — | — | — | — |
| LIGHT | 0.6303 | 1.1905 | 1.1494 | 0.7901 |
| ABSORBENT/WATER- | | | | |
| SOLUBLE RESIN | | | | |

TABLE 4

| | EXAM- | EXAM- | EXAM- | EXAM- |
|---|---|---|---|---|
| | PLE 13 | PLE 14 | PLE 15 | PLE 16 |
| WATER-SOLUBLE | PVP K- | PVP K- | PVP K- | HPC- |
| RESIN | 90: 4.49 | 30: 0.78 | 60: 4.20 | L: 5.10 |
| | | PVP K- | PVP K- | |
| | | 85N: 5.67 | 85N: 4.20 | |
| WATER | 78.11 | 72.03 | 70.69 | 75.89 |
| LIGHT ABSORBENT | αGR: 2.50 | αGR: 7.50 | αGR: 6.00 | αGR: 5.00 |
| ORGANIC SOLVENT | PGME: 14.89 | PGME: 14.00 | PGME: 14.90 | PGME: 14.00 |
| ANTIOXIDANT | ASC: 0.010 | ASC: 0.020 | ASC: 0.010 | ASC: 0.010 |
| PLASTICIZER | — | — | — | — |
| LIGHT | 0.5568 | 1.1628 | 0.7143 | 0.9804 |
| ABSORBENT/WATER- | | | | |
| SOLUBLE RESIN | | | | |

Specifically, a solution was prepared by dissolving, in water, water-soluble resin as powder (either polyvinyl alcohol (PVA 5-88) having a polymerization degree of approximately 500 and having a saponification degree of approximately 88, polyvinylpyrrolidone (PVP K-30, 60, 85N, or 90) having a K-value of approximately 30, approximately 60, approximately 85, or approximately 90, or hydroxypropyl cellulose (HPC-L) having a molecular weight of approximately 140,000, or two of these), thereafter adding an antioxidant (ASC) or/and a plasticizer (TMP) as needed, and then adding a light absorbent (αGR). The protective film agents of Examples 1 through 16 were obtained by further dissolving an organic solvent (propylene glycol monomethyl ether (PGME)) in the solution, thereafter effecting an ion exchange in such a manner as to make the content of metallic impurities equal to or less than 100 ppb, and then performing filtering.

In addition, there were also prepared protective film agents of Comparative Examples 1 through 6 which contain various kinds of materials at ratios (percent by mass) illustrated in Tables 5 and 6 below.

TABLE 5

| | COMPARATIVE | COMPARATIVE | COMPARATIVE | COMPARATIVE |
|---|---|---|---|---|
| | EXAMPLE 1 | EXAMPLE 2 | EXAMPLE 3 | EXAMPLE 4 |
| WATER-SOLUBLE | PVA 5- | PVA 5- | PVA 5- | PVP K- |
| RESIN | 88: 12.41 | 88: 13.24 | 88: 13.33 | 60: 13.54 |
| WATER | 67.68 | 66.85 | 66.76 | 67.43 |
| LIGHT ABSORBENT | αGR: 5.00 | αGR: 5.00 | αGR: 5.00 | αGR: 5.00 |
| ORGANIC SOLVENT | PGME: 14.90 | PGME: 14.90 | PGME: 14.90 | PGME: 14.02 |
| ANTIOXIDANT | ASC: 0.010 | ASC: 0.010 | ASC: 0.010 | ASC: 0.010 |
| PLASTICIZER | — | — | — | — |
| LIGHT | 0.4029 | 0.3776 | 0.3751 | 0.3692 |
| ABSORBENT/WATER- | | | | |
| SOLUBLE RESIN | | | | |

TABLE 6

| | COMPARATIVE | COMPARATIVE |
|---|---|---|
| | EXAMPLE 5 | EXAMPLE 6 |
| WATER-SOLUBLE | PVP K- | PVP K- |
| RESIN | 60: 14.58 | 60: 15.00 |
| WATER | 68.07 | 69.48 |
| LIGHT ABSORBENT | αGR: 3.33 | αGR: 1.50 |
| ORGANIC SOLVENT | PGME: 14.01 | PGME: 14.01 |
| ANTIOXIDANT | ASC: 0.010 | ASC: 0.010 |
| PLASTICIZER | — | — |
| LIGHT | 0.2283 | 0.1000 |
| ABSORBENT/WATER- | | |
| SOLUBLE RESIN | | |

Specifically, water-soluble resin (PVA 5-88 or PVP K-60) as powder was dissolved in water. An antioxidant (ASC) was thereafter added. In addition, a light absorbent (αGR) was dissolved in an organic solvent (PGME). The protective film agents of Comparative Examples 1 through 6 were obtained by further mixing the two solutions, that is, the solution including the water, the water-soluble resin, and the antioxidant and the solution including the organic solvent and the light absorbent, thereafter effecting an ion exchange in such a manner as to make the content of metallic impurities equal to or less than 100 ppb, and then performing filtering.

Then, the presence or absence of turbidity immediately after the preparation of each of the protective film agents of Examples 1 through 16 and Comparative Examples 1 through 6 and at a time point of ending storage for one month was evaluated. Incidentally, this evaluation was performed by combining a visual inspection and a measurement using a spectrophotometer (UV-visible spectrophotometer UV-2700 manufactured by Shimadzu Corporation). Specifically, first, the presence or absence of turbidity in each of the protective film agents is evaluated by a visual inspection. Then, an evaluation indicating that there is turbidity is made when the absorbance of a predetermined wavelength existing in a visible light range of an absorption spectrum obtained by further measuring, by the spectrophotometer, a protective film agent evaluated as not being turbid by a visual inspection is equal to or more than a threshold value. An evaluation indicating that there is no turbidity is made when the absorbance is less than the threshold value. Table 7 below indicates a result of the evaluation.

TABLE 7

| | | PRESENCE OR ABSENCE |
|---|---|---|
| | PRESENCE OR ABSENCE | OF TURBIDITY |
| | OF TURBIDITY | AT TIME POINT |
| | IMMEDIATELY | OF ENDING STORAGE |
| | AFTER PREPARATION | FOR ONE MONTH |
| EXAMPLE 1 | ABSENT | ABSENT |
| EXAMPLE 2 | ABSENT | ABSENT |
| EXAMPLE 3 | ABSENT | ABSENT |
| EXAMPLE 4 | ABSENT | ABSENT |
| EXAMPLE 5 | ABSENT | ABSENT |
| EXAMPLE 6 | ABSENT | ABSENT |
| EXAMPLE 7 | ABSENT | ABSENT |
| EXAMPLE 8 | ABSENT | ABSENT |
| EXAMPLE 9 | ABSENT | ABSENT |
| EXAMPLE 10 | ABSENT | ABSENT |
| EXAMPLE 11 | ABSENT | ABSENT |
| EXAMPLE 12 | ABSENT | ABSENT |
| EXAMPLE 13 | ABSENT | ABSENT |
| EXAMPLE 14 | ABSENT | ABSENT |
| EXAMPLE 15 | ABSENT | ABSENT |
| EXAMPLE 16 | ABSENT | ABSENT |
| COMPARATIVE | PRESENT | — |
| EXAMPLE 1 | | |
| COMPARATIVE | PRESENT | — |
| EXAMPLE 2 | | |
| COMPARATIVE | PRESENT | — |
| EXAMPLE 3 | | |
| COMPARATIVE | ABSENT | PRESENT |
| EXAMPLE 4 | | |
| COMPARATIVE | ABSENT | PRESENT |
| EXAMPLE 5 | | |
| COMPARATIVE | ABSENT | PRESENT |
| EXAMPLE 6 | | |

Based on this evaluation, it has been found that whereas turbidity occurs within one month from the preparation in each of the protective film agents of Comparative Examples 1 through 6 that contain 40.29 parts by mass or less of the light absorbent relative to 100 parts by mass of the water-soluble resin, no turbidity occurs even at a time point of ending storage for one month in each of the protective film agents of Examples 1 through 16 that contain 52.03 parts by mass or more of the light absorbent relative to 100 parts by mass of the water-soluble resin. It is hence recognized that preparing a protective film agent such that the protective film agent contains 52.00 parts by mass or more of the light absorbent relative to 100 parts by mass of the water-soluble resin makes the protective film agent less likely to become turbid during storage.

A description will next be made of an experiment (Experiment 2) conducted to investigate the content of an antioxidant that excels in a function of improving the stability of the protective film agent as an example of the present invention. In Experiment 2, first, there were prepared four protective film agents which contain an antioxidant at ratios (percent by mass) illustrated in Table 8 below. Specifically, the following were prepared: the protective film agent of Example 10 described in the above Table 3; and a protective film agent that contain various kinds of materials at the same ratio as the protective film agent of Example 10 except that the content of the antioxidant is 0.005 percent by mass, 0.010 percent by mass, or 0.030 percent by mass.

TABLE 8

| ANTIOXIDANT: | STORAGE | STORAGE | STORAGE | STORAGE | STORAGE |
|---|---|---|---|---|---|
| PERCENT BY | FOR ONE | FOR TWO | FOR FOUR | FOR SIX | FOR NINE |
| MASS | MONTH | MONTHS | MONTHS | MONTHS | MONTHS |
| EXAMPLE 10 | 0.96 | 0.98 | 1.04 | 1.14 | 1.29 |
| ASC: 0.005 | 0.97 | 0.95 | 0.93 | 0.97 | 1.06 |
| ASC: 0.010 | 0.96 | 0.94 | 0.93 | 0.93 | 0.95 |
| ASC: 0.030 | 0.99 | 0.94 | 0.94 | 0.97 | 1.01 |

Then, the following were measured: the initial absorbance of each of the four protective film agents for light having a wavelength of 470 nm; and the absorbance of each of the four protective film agents for light having a wavelength of 470 nm at time points of ending storage for one month, two months, four months, six months, and nine months while the temperature of the atmosphere is maintained at 23° C. Numbers provided in the columns of “STORAGE FOR ONE MONTH,” “STORAGE FOR TWO MONTHS,” “STORAGE FOR FOUR MONTHS,” “STORAGE FOR SIX MONTHS,” and “STORAGE FOR NINE MONTHS” in the above Table 8 denote values obtained by dividing each absorbance at the time points of ending storage for one month, two months, four months, six months, and nine months by the initial absorbance. Based on these measurements, it is recognized that the protective film agent is preferably prepared in such a manner as to contain 0.005 percent by mass or more of the antioxidant from a viewpoint of improving the stability of the protective film agent.

A description will next be made of an experiment (Experiment 3) conducted to investigate the content of a plasticizer that excels in a function of improving the stability of the protective film agent. In Experiment 3, first, there were prepared four protective film agents which contain various kinds of materials at ratios (percent by mass) illustrated in Table 9 below.

TABLE 9

| | | | | |
|---|---|---|---|---|
| WATER-SOLUBLE | PVA 5- | PVA 5- | PVA 5- | PVA 5- |
| RESIN | 88: 10.50 | 88: 10.26 | 88: 9.72 | 88: 9.32 |
| WATER | 69.69 | 67.43 | 63.97 | 60.56 |
| LIGHT | αGR: 5.00 | αGR: 5.00 | αGR: 5.00 | αGR: 5.00 |
| ABSORBENT | | | | |
| ORGANIC | PGME: 14.80 | PGME: 14.80 | PGME: 14.80 | PGME: 14.80 |
| SOLVENT | | | | |
| ANTIOXIDANT | ASC: 0.010 | ASC: 0.010 | ASC: 0.010 | ASC: 0.010 |
| PLASTICIZER | — | TMP: 2.50 | TMP: 6.50 | TMP: 10.30 |
| STORAGE FOR | ≥15% | 10% to 15% | 1% to 5% | ≤1% |
| ONE MONTH | | | | |

Then, the following were measured: the initial absorbance of each of the four protective film agents for light having a wavelength of 470 nm; and the absorbance of each of the four protective film agents for light having a wavelength of 470 nm at a time point of ending storage for one month while the temperature of the atmosphere is maintained at 23° C. A number provided in the section of “STORAGE FOR ONE MONTH” in the above Table 9 denotes a rate of change (percent) in absorbance at a time point of ending storage for one month from the initial absorbance. Based on these measurements, it is recognized that the protective film agent is preferably prepared in such a manner as to contain 2.5 percent by mass or more of the plasticizer from a viewpoint of improving the stability of the protective film agent.

Incidentally, the pH of each of the protective film agents of Examples 1 through 16 was equal to or more than 3.0 but equal to or less than 3.5. From a viewpoint of suppressing bacterial growth in the protective film agent, the pH of the protective film agent is preferably equal to or more than 2.5 but equal to or less than 4.0. Meanwhile, depending on the type of the devices formed in the workpiece having the protective film agent coated with the one surface thereof, the devices may be adversely affected by the protective film agent whose pH is equal to or more than 3.0 but equal to or less than 3.5, that is, which is relatively strongly acid.

From a viewpoint of suppressing the adverse effect on the devices, the protective film agent may be prepared such that the pH thereof is equal to or more than 4.0 but equal to or less than 8.0. For example, the pH of each of the protective film agents of Examples 1 through 16 may be shifted from 3.0 or more but 3.5 or less to 4.0 or more but 8.0 or less by adding a pH adjuster such as an amine-based compound or an ammonium-based compound to each of the protective film agents.

However, when the pH of the protective film agent becomes equal to or more than 4.0 but equal to or less than 8.0, bacteria may grow easily in the protective film agent. Such bacterial growth can be suppressed by, for example, adding a benzoic acid, a paraben-based compound, or the like to the protective film agent.

A description will next be made of an experiment (Experiment 4) conducted to investigate the quality of the protective film formed from the protective film agent as an example of the present invention. In Experiment 4, first, the following were prepared: the protective film agent of Example 11 described in the above Table 3; and a protective film agent of Comparative Example 7 that contain ferulic acid (FA) instead of αGR as the light absorbent and contain various kinds of materials at a ratio (percent by mass) illustrated in Table 10 below.

TABLE 10

| | COMPARATIVE |
|---|---|
| | EXAMPLE 7 |
| WATER-SOLUBLE | PVP K- |
| RESIN | 90: 6.40 |
| WATER | 79.30 |
| LIGHT | FA: 0.30 |
| ABSORBENT | |
| ORGANIC | PGME: 14.00 |
| SOLVENT | |
| ANTIOXIDANT | ASC: 0.003 |
| PLASTICIZER | — |

In addition, a diluted solution A was prepared by diluting 200 times a supernatant liquid collected from the protective film agent of Example 11, and a diluted solution B was prepared by diluting 200 times a supernatant liquid collected from the protective film agent of Comparative Example 7. Then, the absorbance of each of the diluted solutions A and B was measured. Incidentally, this measurement was performed by using the UV-visible spectrophotometer UV-2700 manufactured by Shimadzu Corporation. Table 11 below illustrates the absorbance of each of the diluted solutions A and B at a wavelength of 355 nm.

TABLE 11

| | ABSORBANCE |
|---|---|
| DILUTED | 0.19 |
| SOLUTION A | |
| DILUTED | 5.57 |
| SOLUTION B | |

Then, a protective film (first protective film) was formed by applying the protective film agent of Example 11 to the one surface of the workpiece (first workpiece) and thereafter drying the protective film agent, and a protective film (second protective film) was formed by applying the protective film agent of Comparative Example 7 to the one surface of the workpiece (second workpiece) and thereafter drying the protective film agent.

Incidentally, each protective film was formed by using a spin coating method, specifically, supplying the protective film agent to the one surface of the workpiece, then rotating the workpiece until the entire region of the one surface was covered with the protective film agent, and thereafter drying the protective film agent. Conditions of the spin coating method and the film thickness of the formed protective films at this time are as illustrated in Table 12 below.

TABLE 12

| | PROTECTIVE | | FILM |
|---|---|---|---|
| | FILM AGENT | CONDITIONS | THICKNESS |
| FIRST | EXAMPLE 11 | 2000 RPM, | 1.1 μm |
| WORKPIECE | | 60 SECONDS | |
| SECOND | COMPARATIVE | 2000 RPM, | 1.1 μm |
| WORKPIECE | EXAMPLE 7 | 60 SECONDS | |

Further, a linear groove that penetrates each of the protective films and partially exposes each of the workpieces was formed by irradiation of each of the protective films with a laser beam having a wavelength that is absorbed by αGR and FA. Incidentally, processing conditions (laser beam irradiation conditions) at this time were as follows.
Beam size: 65×5 μm
Wavelength: 355 nm
Power: 5 to 10 W
Frequency: 100 to 1000 kHz
Feed speed: 500 to 1000 mm/s
Number of passes: 10 to 20 passes

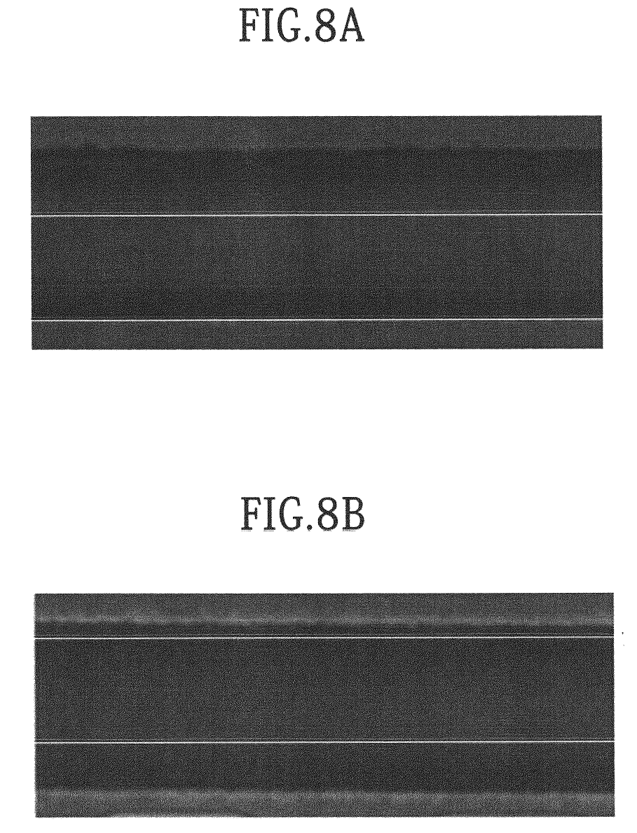

FIG. 8A is an optical microscopic image illustrating a linear groove obtained after formation of the groove that penetrates the first protective film and partially exposes the first workpiece and cleaning of the first workpiece with water to remove the first protective film. FIG. 8B is an optical microscopic image illustrating a linear groove obtained after formation of the groove that penetrates the second protective film and partially exposes the second workpiece and cleaning of the second workpiece with water to remove the second protective film.

Experiment 4 indicates that a part in the vicinity of the groove in the second workpiece is discolored in a case where the groove is formed by irradiation of the second workpiece with the laser beam via the protective film formed from the protective film agent of Comparative Example 7 (see FIG. 8B), whereas the discoloration of a part in the vicinity of the groove in the first workpiece is suppressed in a case where the groove is formed by irradiation of the first workpiece with the laser beam via the protective film formed from the protective film agent of Example 11 (see FIG. 8A). That is, based on Experiment 4, it is recognized that the protective film agent of Example 11 can form a protective film of excellent quality as compared with the protective film agent of Comparative Example 7.

Further, an evaluation was also performed with regard to a laser burn of the workpiece having a plurality of image sensors formed on the one surface side thereof (specifically, the burning of the workpiece by scattered light during laser processing).

A protective film (third protective film) was formed by applying the protective film agent of Example 11 to the one surface of a workpiece (third workpiece) having a plurality of image sensors formed on the one surface side thereof and drying the protective film agent, and a protective film (fourth protective film) was formed by applying the protective film agent of Comparative Example 7 to the one surface of a workpiece (fourth workpiece) having a plurality of image sensors formed on the one surface side thereof and drying the protective film agent.

Incidentally, each of the protective films was formed by use of the spin coating method. Conditions of the spin coating method and the film thickness of the formed protective films at this time are as illustrated in Table 13 below.

TABLE 13

| | PROTECTIVE | | FILM |
|---|---|---|---|
| | FILM AGENT | CONDITIONS | THICKNESS |
| THIRD | EXAMPLE 11 | 400 rpm, | 2.6 μm |
| WORKPIECE | | 360 SECONDS | |
| FOURTH | COMPARATIVE | 400 rpm, | 2.6 μm |
| WORKPIECE | EXAMPLE 7 | 360 SECONDS | |

Further, a linear groove that penetrates each of the protective films and partially exposes each of the workpieces was formed by irradiation of each of the protective films with a laser beam having a wavelength that is absorbed by αGR and FA. Incidentally, processing conditions (laser beam irradiation conditions) at this time were as follows.
Beam size: 65×5 μm
Wavelength: 355 nm
Power: 5 to 10 W
Frequency: 100 to 1000 kHz
Feed speed: 500 to 1000 mm/s
Number of passes: 10 to 20 passes

Many laser burns were observed at a part in the vicinity of the groove in the fourth workpiece in a case where the groove was formed by irradiation of the fourth workpiece with the laser beam via the protective film formed from the protective film agent of Comparative Example 7, whereas no laser burn was observed at a part in the vicinity of the groove in the third workpiece in a case where the groove was formed by irradiation of the third workpiece with the laser beam via the protective film formed from the protective film agent of Example 11. It is recognized that laser burns of the workpiece can be prevented by forming the protective film from the protective film agent in which the light absorbent is αGR and which has a high content thereof (that is, has a high absorbance for the wavelength of the laser beam).

Besides, structures, methods, and the like according to the foregoing embodiment can be modified and implemented as appropriate without departing from the objective scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A protective film agent for forming a protective film on one surface of a workpiece before processing the workpiece,
wherein the protective film agent is a solution including water-soluble resin, water, and a light absorbent,
the light absorbent has a flavone structure, a flavonol structure, or an isoflavone structure, and
the protective film agent contains 52.00 parts by mass or more of the light absorbent relative to 100 parts by mass of the water-soluble resin.

2. The protective film agent according to claim 1, wherein
the water-soluble resin is polyvinyl alcohol, polyvinylpyrrolidone, hydroxypropyl cellulose, or polyoxazoline.

3. The protective film agent according to claim 1, wherein
the light absorbent has the flavone structure.

4. The protective film agent according to claim 3, wherein
the light absorbent is α-glucosyl rutin.

5. The protective film agent according to claim 1, wherein
content of metallic impurities is equal to or less than 100 ppb.

6. The protective film agent according to claim 1, further comprising:
an antioxidant or/and a plasticizer.

7. The protective film agent according to claim 6, wherein
content of the antioxidant is 0.005 percent by mass or more, and
content of the plasticizer is 2.5 percent by mass or more.

8. The protective film agent according to claim 6, wherein
the antioxidant is an L-ascorbic acid or an ascorbic acid derivative.

9. A chip manufacturing method for manufacturing chips by dividing a workpiece in which a plurality of devices are formed, along boundaries between the plurality of devices, the chip manufacturing method comprising:
applying a protective film agent as a solution including water-soluble resin, water, and a light absorbent to one surface of the workpiece;
forming a protective film by drying the protective film agent applied to the one surface;
partially removing the protective film and partially exposing the workpiece by irradiating the workpiece with a pulsed laser beam having a wavelength that is absorbed by the light absorbent along the boundaries from the one surface side on which the protective film is formed; and
dividing the workpiece into a plurality of chips by subjecting the workpiece to plasma etching with the partially removed protective film used as a mask,
the light absorbent having a flavone structure, a flavonol structure, or an isoflavone structure, and
the protective film agent containing 52.00 parts by mass or more of the light absorbent relative to 100 parts by mass of the water-soluble resin.

10. The chip manufacturing method according to claim 9, wherein
each of the plurality of devices is an image sensor.

11. A chip manufacturing method for manufacturing chips by dividing a workpiece on which a plurality of devices are formed, along boundaries between the plurality of devices, the chip manufacturing method comprising:
applying a protective film agent as a solution including water-soluble resin, water, and a light absorbent to one surface of the workpiece;
forming a protective film by drying the protective film agent applied to the one surface; and
partially removing each of the protective film and the workpiece and dividing the workpiece into a plurality of chips by irradiating the workpiece with a pulsed laser beam having a wavelength that is absorbed by each of the light absorbent and the workpiece along the boundaries from the one surface side on which the protective film is formed,
the light absorbent having a flavone structure, a flavonol structure, or an isoflavone structure, and
the protective film agent containing 52.00 parts by mass or more of the light absorbent relative to 100 parts by mass of the water-soluble resin.

12. The chip manufacturing method according to claim 11, wherein
each of the plurality of devices is an image sensor.
